(19) United States
(12) Patent Application Publication
(10) Pub. No.: US 2024/0022696 A1
(43) Pub. Date: Jan. 18, 2024

(54) LASER PROJECTION APPARATUS

(71) Applicant: HISENSE LASER DISPLAY CO., LTD, Qingdao (CN)

(72) Inventors: Xin ZHANG, Qingdao (CN); Youliang TIAN, Qingdao (CN); Ke YAN, Qingdao (CN); Zinan ZHOU, Qingdao (CN); Yao LU, Qingdao (CN)

(73) Assignee: HISENSE LASER DISPLAY CO., LTD, Qingdao (CN)

(21) Appl. No.: 18/476,085

(22) Filed: Sep. 27, 2023

Related U.S. Application Data
(63) Continuation of application No. PCT/CN2022/116368, filed on Aug. 31, 2022.

(30) Foreign Application Priority Data
Sep. 2, 2021 (CN) 202111025826.X
Sep. 9, 2021 (CN) 202111056662.7
Sep. 30, 2021 (CN) 202111160879.2
Sep. 30, 2021 (CN) 202111163821.3

(51) Int. Cl. H04N 9/31

(52) U.S. Cl. CPC H04N 9/3161; H04N 9/3155; H04N 9/3164

(57) ABSTRACT

A laser projection apparatus includes a laser source assembly, a light modulation assembly, and a projection lens. The laser source assembly includes a laser device. The laser device includes a base plate, a frame, a first light-emitting chip, a first reflecting portion, a first collimating portion, and a light homogenizing component. The first light-emitting chip is configured to emit a first laser beam. The first collimating portion is located in a sealed space and configured to collimate the first laser beam, so as to transmit the first laser beam to the light homogenizing component in a direction perpendicular to the base plate. The light homogenizing component is disposed on a side of the frame away from the base plate and configured to homogenize the first laser beam and propagate the first laser beam out of the sealed space.

### CROSS-REFERENCE TO RELATED APPLICATIONS

This application is a continuation application of International Patent Application No. PCT/CN2022/116368, filed on Aug. 31, 2022, which claims priority to Chinese Patent Application No. 202111025826.X, filed on Sep. 2, 2021; Chinese Patent Application No. 202111056662.7, filed on Sep. 9, 2021; Chinese Patent Application No. 202111160879.2, filed on Sep. 30, 2021; and Chinese Patent Application No. 202111163821.3, filed on Sep. 30, 2021, which are incorporated herein by reference in their entireties.

### TECHNICAL FIELD

The present disclosure relates to the field of display technologies and, in particular, to a laser projection apparatus.

### BACKGROUND

Laser projection apparatus includes a laser source assembly, a light modulation assembly, and a projection lens. Illumination beams provided by the laser source assembly are modulated by the light modulation assembly to become projection beams, and the projection beams are projected onto a screen or a wall by the projection lens, so as to display a projection image. A laser device in the laser source assembly includes a plurality of light-emitting chips arranged in an array, and the plurality of light-emitting chips are configured to emit laser beams.

### SUMMARY

A laser projection apparatus is provided. The laser projection apparatus includes a laser source assembly, a light modulation assembly, and a projection lens. The laser source assembly is configured to provide illumination beams. The light modulation assembly is configured to modulate the illumination beams with an image signal, so as to obtain projection beams. The projection lens is configured to project the projection beams into an image. The laser source assembly includes a laser device. The laser device includes a base plate, a frame, at least one first light-emitting chip, a first reflecting portion, a first collimating portion, and a light homogenizing component. The frame is disposed on the base plate, and a sealed space is defined between the frame, the base plate, and the light homogenizing component. The first light-emitting chip is disposed on the base plate and located in the sealed space. The first light-emitting chip is configured to emit a first laser beam. A laser-exit direction of the first light-emitting chip is parallel to the base plate. The first reflecting portion is disposed on the base plate and located in the sealed space. The first reflecting portion is located on a laser-exit side of the first light-emitting chip and configured to guide the first laser beam to a direction away from the base plate. The first collimating portion is located in the sealed space and configured to collimate the first laser beam, so as to transmit the first laser beam to the light homogenizing component in a direction perpendicular to the base plate. The light homogenizing component is disposed on a side of the frame away from the base plate and configured to homogenize the first laser beam and propagate the first laser beam out of the sealed space, so that the first laser beam constitutes at least a part of the illumination beams. The light homogenizing component includes a body, a first convex lens, and a second convex lens. The first convex lens is located on a side of the body proximate to the base plate. The second convex lens is located on a side of the body away from the base plate and disposed opposite to the first convex lens. An area of orthogonal projection of any one of the first convex lens and the second convex lens on the body is greater than or equal to an area of a first beam spot of the first laser beam on the light homogenizing component.

### BRIEF DESCRIPTION OF THE DRAWINGS

FIG. 1 is a diagram showing a structure of a laser projection apparatus, in accordance with some embodiments;

FIG. 2 is a timing diagram of a laser source assembly in a laser projection apparatus, in accordance with some embodiments;

FIG. 3 is a diagram showing a beam path of a laser projection apparatus, in accordance with some embodiments;

FIG. 4 is a diagram showing a structure of an optical filter portion, in accordance with some embodiments:

FIG. 5 is a diagram showing an arrangement of micromirrors in a digital micromirror device, in accordance with some embodiments;

FIG. 6 is a diagram showing a swing position of a micromirror in the digital micromirror device shown in FIG. 5;

FIG. 7 is a schematic diagram showing operation of micromirrors, in accordance with some embodiments;

FIG. 8 is a diagram showing another structure of a laser projection apparatus, in accordance with some embodiments;

FIG. 9 is a diagram showing a beam path of a laser projection apparatus in the related art;

FIG. 10 is a diagram showing a structure of a laser device, in accordance with some embodiments;

FIG. 11 is a diagram showing a structure of a laser source in the related art;

FIG. 12 is a diagram showing a structure of another laser device, in accordance with some embodiments;

FIG. 13 is a diagram showing a structure of yet another laser device, in accordance with some embodiments;

FIG. 14 is a diagram showing a structure of yet another laser device, in accordance with some embodiments;

FIG. 15 is a diagram showing a structure of yet another laser device, in accordance with some embodiments;

FIG. 16 is a diagram showing a structure of yet another laser device, in accordance with some embodiments;

FIG. 17 is a top view of a laser device, in accordance with some embodiments;

FIG. 18 is a top view of yet another laser device, in accordance with some embodiments;

FIG. 19 is a top view of yet another laser device, in accordance with some embodiments;

FIG. 20 is a top view of yet another laser device, in accordance with some embodiments;

FIG. 21 is a diagram showing a structure of yet another laser device, in accordance with some embodiments;

FIG. 22 is a diagram showing a structure of yet another laser device, in accordance with some embodiments;

FIG. 23 is a diagram showing a beam path of a second collimating portion, in accordance with some embodiments; and

FIG. 24 is a diagram showing a beam path of another second collimating portion, in accordance with some embodiments.

### DETAILED DESCRIPTION

Some embodiments of the present disclosure will be clearly and completely described below with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.” In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, the terms such as “first” and “second” are used for descriptive purposes only and are not to be construed as indicating or implying the relative importance or implicitly indicating the number of indicated technical features. Thus, features defined by “first” or “second” may explicitly or implicitly include one or more of the features. In the description of the embodiments of the present disclosure, the term “a plurality of” or “the plurality of” means two or more unless otherwise specified.

In the description of some embodiments, the expression “connected” and derivative thereof may be used. The term “connected” should be understood in a broad sense. For example, the term “connected” may represent a fixed connection, a detachable connection, or a one-piece connection, or may represent a direct connection, or may represent an indirect connection through an intermediate medium. The embodiments disclosed herein are not necessarily limited to the content herein.

The phrase “at least one of A, B, and C” has the same meaning as the phrase “at least one of A, B, or C,” both including the following combinations of A, B, and C: only A, only B, only C, a combination of A and B, a combination of A and C, a combination of B and C, and a combination of A, B, and C.

The use of the phrase “applicable to” or “configured to” herein means an open and inclusive expression, which does not exclude devices that are applicable to or configured to perform additional tasks or steps.

The term such as “about,” “substantially,” and “approximately” as used herein includes a stated value and an average value within an acceptable range of deviation of a particular value. The acceptable range of deviation is determined by a person of ordinary skill in the art, considering measurement in question and errors associated with measurement of a particular quantity (i.e., limitations of a measurement system).

The term such as “parallel,” “perpendicular,” or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system).

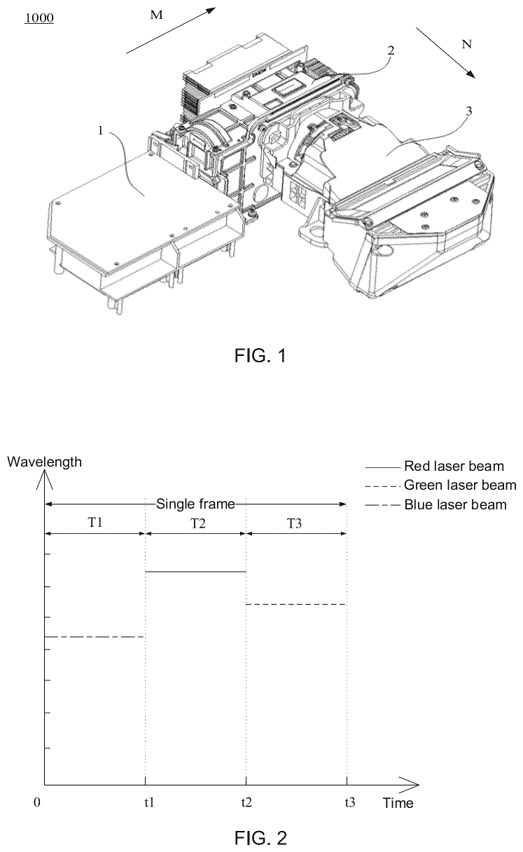

In some embodiments of the present disclosure, a laser projection apparatus is provided. As shown in FIG. 1, the laser projection apparatus 1000 includes a laser source assembly 1, a light modulation assembly 2, and a projection lens 3. The laser source assembly 1 is configured to provide illumination beams. The light modulation assembly 2 is configured to modulate the illumination beams provided by the laser source assembly 1 with image signals, so as to obtain projection beams. The projection lens 3 is configured to project the projection beams into an image on a screen or a wall.

The laser source 1, the light modulation assembly 2, and the projection lens 3 are sequentially connected in a propagation direction of beams. In some examples, an end of the light modulation assembly 2 is connected to the laser source assembly 1, and the laser source assembly 1 and the light modulation assembly 2 are arranged in an exit direction (referring to the direction M shown in FIG. 1) of the illumination beams of the laser projection apparatus 1000. Another end of the light modulation assembly 2 is connected to the projection lens 3, and the light modulation assembly 2 and the projection lens 3 are arranged in an exit direction (referring to the direction N shown in FIG. 1) of the projection beams of the laser projection apparatus 1000.

In some examples, as shown in FIG. 1, the exit direction M of the illumination beams of the laser projection apparatus 1000 is substantially perpendicular to the exit direction N of the projection beams of the laser projection apparatus 1000. In this way, the structural arrangement of the laser projection apparatus 1000 may be made reasonable, and a length of a beam path of the laser projection apparatus 1000 in a direction (e.g., the direction M or the direction N) may be prevented from being too long.

In some embodiments, the laser source assembly 1 may sequentially provide beams of three primary colors (i.e., beams of red color, green color, and blue color). In some other embodiments, the laser source assembly 1 may simultaneously output the beams of three primary colors, so as to continuously emit white beams. Of course, the illumination beams provided by the laser source assembly 1 may also include beams other than beams of the three primary colors, such as beams of yellow. The laser source assembly 1 includes a laser device. The laser device may emit laser beams of at least one color, such as blue laser beams.

In some examples, as shown in FIG. 2, during a projection process of a frame of an image, the laser source assembly 1 may sequentially output blue laser beams, red laser beams, and green laser beams. For example, the laser source assembly 1 outputs the blue laser beams in a first period T1, the red laser beams in a second period T2, and the green laser beams in a third period T3. In such example, time for the laser source assembly 1 to accomplish the sequential output of each of three primary color beams once is a cycle for the laser source assembly 1 to output the three primary color beams. In a display cycle of the frame of the image, the laser source assembly 1 performs the sequential output of each of three primary color beams once. Therefore, the display cycle of the frame of the image and the cycle for the laser source assembly 1 to output the three primary color beams are equal to each other and are both equal to a sum of the first period T1, the second period T2, and the third period T3. In such example, due to a phenomenon of visual persistence of human eyes, the human eyes will superimpose the colors of the blue laser beams, red laser beams, and green laser beams that are sequentially output. Therefore, what the human eyes see is white beams formed by combining the beams of three primary colors.

Structures of the laser source assembly 1, the light modulation assembly 2, and the projection lens 3 are described below with reference to the accompanying drawings.

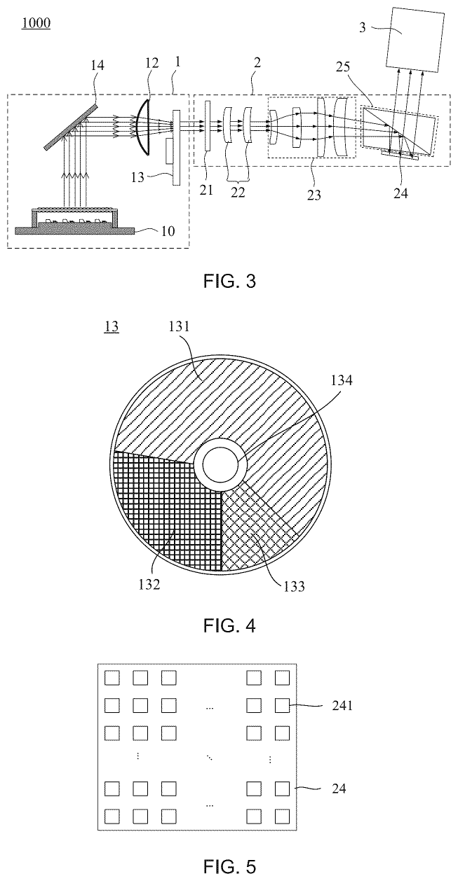

Referring to FIG. 3, the laser source assembly 1 includes a laser device 10, a combining lens group 14, a converging lens group 12, and an optical filter portion 13. The laser device 10 is configured to provide the illumination beams. The combining lens group 14 is disposed on a laser-exit side of the laser device 10 and configured to reflect the illumination beams provided by the laser device 10 to the converging lens group 12. The converging lens group 12 is disposed on a laser-exit side of the combining lens group 14 and configured to converge the illumination beams from the combining lens group 14. The optical filter portion 13 is disposed on a laser-exit side of the converging lens group 12 and configured to filter the illumination beams converged by the converging lens group 12, so as to sequentially output beams of three primary colors.

In some embodiments, the combining lens group 14 may be a dichroic mirror. In a case where the laser source assembly 1 outputs the beams of three primary colors (that is, the laser device 10 outputs the beams of three primary colors) simultaneously or sequentially, the combining lens group 14 may adjust the red laser beams, green laser beams, and blue laser beams emitted by the laser device 10 to a substantially same beam path and reflect them to the converging lens group 12.

In some embodiments, the converging lens group 12 may include at least one piano-convex lens, and a convex surface of the at least one plano-convex lens faces the combining lens group 14. Of course, the converging lens group 12 may further include a plurality of convex lenses, and the present disclosure is not limited thereto.

In some embodiments, as shown in FIG. 4, the optical filter portion 13 includes a green optical filter 131, a blue optical filter 132, a red optical filter 133, and a driving portion 134. The driving portion 134 is configured to drive the plurality of optical filters to rotate, so that the illumination beams emitted by the laser device 10 may be filtered by the optical filters of different colors during the display cycle of the frame of the image. In some examples, in a case where the laser device 10 simultaneously outputs the beams of three primary colors, and the optical filter portion 13 is rotated to a position where the red optical filter 133 covers the beam spots of the beams of the three primary colors, beams of other colors except for the red laser beams in the beams of three primary colors are blocked, while the red laser beams pass through the red optical filter 133. Of course, the optical filter portion 13 may further include optical filters of other colors, and the present disclosure is not limited thereto.

The illumination beams emitted by the laser source assembly 1 enter the light modulation assembly 2. Referring to FIG. 3, the light modulation assembly 2 includes a digital micromirror device (DMD) 24.

The digital micromirror device 24 is located on a laser-exit side of the laser source assembly 1 and configured to use image signals to modulate the illumination beams provided by the laser source assembly 1, so as to obtain the projection beams and reflect the projection beams to the projection lens 3. The digital micromirror device 24 may control the projection beams to display different luminance or gray scales according to different pixels in the image to be displayed, so as to finally produce a projection image. Therefore, the digital micromirror device 24 is also referred to as a light modulation device (or light valve). In addition, the light modulation assembly 2 may be classified as a single-chip system, a double-chip system, or a three-chip system according to the number of the digital micromirror devices 24 used in the light modulation assembly 2.

It will be noted that, in some embodiments of the present disclosure, the light modulation assembly 2 shown in FIG. 3 applies a digital light processing (DLP) projection architecture. Therefore, the light modulation device in some embodiments of the present disclosure is the digital micromirror device. However, the present disclosure does not limit the architecture applied to the light modulation assembly 2 and the type of the light modulation device.

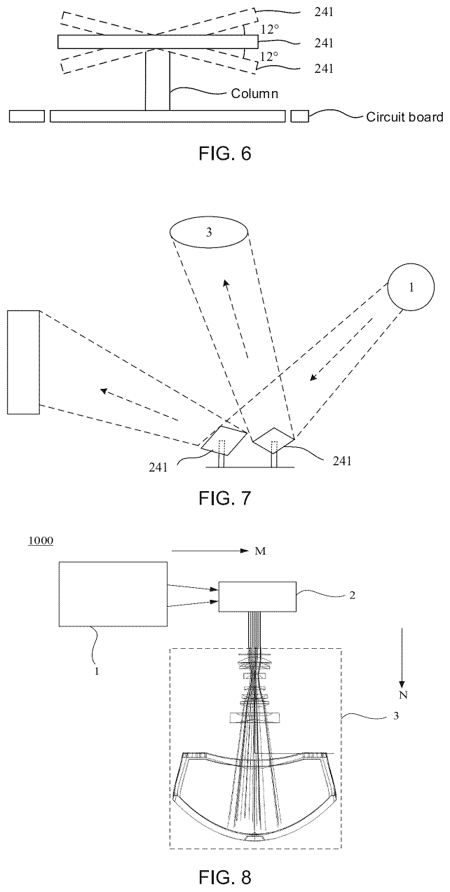

As shown in FIG. 5, the DMD 24 includes thousands of micromirrors 241 that may be individually driven to rotate. These micromirrors 241 are arranged in an array. One micromirror 241 corresponds to one pixel in the image to be displayed. As shown in FIG. 6, in the DLP projection architecture, each micromirror 241 is equivalent to a digital switch, and may swing in a range of minus 12° to plus 12⁰ (i.e., ±12⁰) or a range of minus 17° to plus 17° (i.e., ±17°) due to an action of an external force. FIG. 6 is illustrated by considering an example in which each micromirror 241 may swing in a range of minus 12° to plus 12° (i.e., ±12°).

As shown in FIG. 7, a laser beam reflected by the micromirror 241 at a negative deflection angle is referred to as an OFF laser beam. The OFF laser beam is an ineffective laser beam. A laser beam reflected by the micromirror 241 at a positive deflection angle is referred to as an ON laser beam. The ON laser beam is an effective beam reflected at a positive deflection angle by the micromirror 241 on a surface of the DMD 24 when the micromirror 241 receives irradiation of the illumination beams and the ON laser beam enters the projection lens 3 for projection imaging. An ON state of the micromirror 241 is a state that the micromirror 241 is in and may be maintained when the illumination beams emitted by the laser source assembly 1 may enter the projection lens 3 after being reflected by the micromirror 241. That is to say, the micromirror 241 is in a state of the positive deflection angle. An OFF state of the micromirror 241 is a state that the micromirror 241 is in and may be maintained when the illumination beams emitted by the laser source assembly 1 does not enter the projection lens 3 after being reflected by the micromirror 241. That is to say, the micromirror 241 is in a state of the negative deflection angle.

In a display cycle of a frame of an image, some or all of the micromirrors 241 may be switched at least once between the ON state and the OFF state, so that gray scales of pixels in the frame image are achieved according to durations that the micromirrors 241 are in the ON state and the OFF state. For example, in a case where the pixels have 256 gray scales from 0 to 255, the micromirrors 241 corresponding to a gray scale 0 are each in the OFF state in an entire display cycle of a frame of an image, the micromirrors 241 corresponding to a gray scale 255 are each in the ON state in the entire display cycle of the frame of the image, and the micromirrors 241 corresponding to a gray scale 127 are each in the ON state for a half of time and in the OFF state for another half of time in the display cycle of the frame of the image. Therefore, by controlling a state that each micromirror 241 in the DMD 24 is in and a duration of each state in the display cycle of a frame of an image through the image signals, luminance (the gray scale) of the pixel corresponding to the micromirror 241 may be controlled, thereby modulating the illumination beams projected onto the DMD 24.

In some embodiments, with reference to FIG. 3, the light modulation assembly 2 further includes a diffusion portion 21, a first lens group 22, a second lens group 23, and a prism group 25. It will be noted that the light modulation assembly 2 may also include fewer or more components than the components shown in FIG. 3, and the present disclosure is not limited thereto.

The diffusion portion 21 (e.g., a diffusion sheet) is located on the laser-exit side of the laser source assembly 1 and configured to diffuse the illumination beams from the laser source assembly 1. The first lens group 22 is located on a laser-exit side of the diffusion portion 21 and configured to converge the illumination beams diffused by the diffusion portion 21. The second lens group 23 is located on a laser-exit side of the first lens group 22 and configured to transmit the illumination beams converged by the first lens group 22 to the prism group 25. The prism assembly 25 is configured to reflect the illumination beams to the digital micromirror device 24.

As shown in FIG. 8, the projection lens 3 includes a combination of a plurality of lenses, which are usually divided by group and are divided into a three-segment combination including a front group, a middle group, and a rear group, or a two-segment combination including a front group and a rear group. The front group is a lens group proximate to a laser-exit side (e.g., a side of the projection lens 3 away from the light modulation assembly 2 in the direction N in FIG. 8) of the laser projection apparatus 1000, and the rear group is a lens group proximate to a laser-exit side (e.g., a side of the projection lens 3 proximate to the light modulation assembly 2 in the opposite direction of the direction N in FIG. 8) of the light modulation assembly 2.

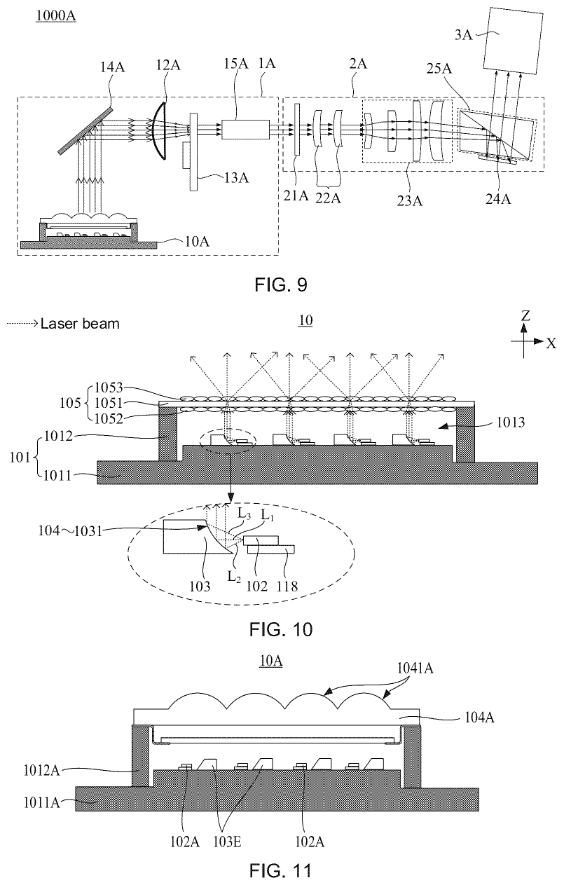

Referring to FIG. 9, in the related art, a laser source assembly 1A of a laser projection apparatus 1000A includes a light pipe 15A. The light pipe 15A is disposed on a laser-exit side of an optical filter portion 13A and configured to homogenize illumination beams filtered by the optical filter portion 13A.

The light pipe 15A may be a tubular device (i.e., a hollow light pipe) spliced by four planar reflecting sheets. Alternatively, the light pipe 15A may also be a solid light pipe. The illumination beams enter an inside of the light pipe 15A from a light inlet of the light pipe 15A, are reflected multiple times inside the light pipe 15A, and then exit from a light outlet of the light pipe 15A, and the illumination beams are homogenized during the process.

However, the laser projection apparatus 1000A in the related art has many components, which is not conducive to the miniaturization of the laser projection apparatus 1000A.

For the above technical problem, a possible improvement solution is that the laser source assembly 1A is not provide with the light pipe 15A, so that the illumination beams filtered by the optical filter portion 13A may directly enter the light modulation assembly 2A. However, such solution may reduce the uniformity of the illumination beams entering the light modulation assembly 2A, thereby reducing the display quality of the projection image.

Another possible improvement solution is that an area of a beam spot of the illumination beams at the light inlet of the light pipe 15A is reduced, so as to reduce the volume of the light pipe 15A. For example, in a case where a converging lens group 12A includes a plano-convex lens, by reducing a radius of curvature of the convex surface of the plano-convex lens, the area of the beam spot of the illumination beams after being converged by the converging lens group 12A is reduced, thereby reducing the area of the beam spot of the illumination beams at the light inlet of the light pipe 15A. However, such solution may cause energy concentration of the illumination beams provided to the light modulation assembly 2A through the light pipe 15A, thereby increasing the probability of overheating damage to components in the light modulation assembly 2A after being irradiated by the illumination beams.

To solve the technical problems existed in the related art and possible improvement solutions, a laser device 10 is provided in the present disclosure.

As shown in FIG. 10, the laser device 10 includes a base plate 1011, a frame 1012, a first light-emitting chip 102, a first reflecting portion 103, a first collimating portion 104, and a light homogenizing component 105.

The frame 1012 is located on the base plate 1011, and a sealed space 1013 is defined between the frame 1012 and the base plate 1011.

The first light-emitting chip 102 is located in the sealed space 1013 and configured to emit a first laser beam. A laser-exit direction of the first light-emitting chip 102 is parallel to the base plate 1011. In some embodiments, the laser device 10 may include a plurality of first light-emitting chips 102.

The first reflecting portion 103 is located in the sealed space 1013 and disposed on a laser-exit side of the first light-emitting chip 102. The first reflecting portion 103 is configured to direct the first laser beam to a direction away from the base plate 1011.

The first collimating portion 104 is located in the sealed space 1013 and configured to collimate the first laser beam and transmit the first laser beam to the light homogenizing component 105.

The light homogenizing component 105 is located on a side of the frame 1012 away from the base plate 1011 and configured to homogenize the first laser beam and propagate the first laser beam out of the sealed space 1013, so that the first laser beam may constitute at least a part of the illumination beams.

The above structure composed of the base plate 1011 and the frame 1012 may be referred to as a tube shell 101, and the sealed space 1013 defined between the base plate 1011 and the frame 1012 may be the sealed space 1013 of the tube shell 101.

In the laser projection apparatus 1000 provided in some embodiments of the present disclosure, the laser device 10 is integrated with the first collimating portion 104 and the light homogenizing component 105, so that the first laser beam with a divergence angle emitted by the first light-emitting chip 102 may become a parallel beam and be transmitted to the light homogenizing component 105 after being collimated by the first collimating portion 104. The light homogenizing component 105 homogenizes the first laser beam collimated by the first collimating portion 104 and propagates the homogenized first laser beam, so that the homogenized first laser beam may constitute at least a part of the illumination beams, thereby improving the uniformity of the illumination beams provided by the laser device 10. In this way, there is no need to additionally arrange a light pipe in the laser source assembly 1 to homogenize the illumination beams, thereby reducing the number of components in the laser source assembly 1 and facilitating the miniaturization of the laser projection apparatus 1000.

In some embodiments, referring to FIG. 10, the first light-emitting chip 102 is disposed on the base plate 1011, and the first reflecting portion 103 is disposed on the base plate 1011. In this way, the heat generated by the first light-emitting chip 102 during operation may be dissipated to the outside of the laser device 10 through the base plate 1011, which is conducive to improving the heat dissipation efficiency of the laser device 10.

Of course, the first light-emitting chip 102 and the first reflecting portion 103 may also be disposed at other positions in the sealed space 1013. For example, the first light-emitting chip 102 is disposed on a first surface of the frame 1012 facing the sealed space 1013 and emits the first laser beam toward the sealed space 1013. The first reflecting portion 103 may be disposed on a second surface of the frame 1012 facing the sealed space 1013, and the first surface is opposite to the second surface.

The following is described by considering an example in which the first light-emitting chip 102 and the first reflecting portion 103 are disposed on the base plate 1011.

In some embodiments, as shown in FIG. 10, the light homogenizing component 105 includes a body 1051, a first convex lens 1052, and a second convex lens 1053. The first convex lens 1052 is located on a side of the body 1051 proximate to the base plate 1011, the second convex lens 1053 is located on a side of the body 1051 away from the base plate 1011, and the second convex lens 1053 is arranged opposite to the first convex lens 1052. For example, in a case where the light homogenizing component 105 includes a plurality of first convex lenses 1052 and a plurality of second convex lenses 1053, the light homogenizing component 105 may be referred to as a fly-eye lens.

The first laser beam collimated by the first collimating portion 104 is transmitted to the first convex lens 1052. The first laser beam is transmitted to the second convex lens 1053 after being converged into a thin beam (i.e., a laser beam with a small beam spot) by the first convex lens 1052. For example, the first convex lens 1052 focuses the first laser beam to a focal point of the second convex lens 1053, and the second convex lens 1053 diffuses the thin beam, so that the thin beam may become a wide beam (i.e., a laser beam with a large beam spot). After a plurality of first laser beams are converged by the plurality of first convex lenses 1052 and diffused by the plurality of second convex lenses 1053, the plurality of first laser beams become a plurality of wide beams, and the beam spots of the plurality of wide beams overlap with each other. In this way, the uniformity and luminance of the first laser beams are improved after the first laser beams pass through the light homogenizing component 105.

In some embodiments, a beam spot of the first laser beam irradiating the light homogenizing component 105 is a first beam spot, an area of an orthogonal projection of the first convex lens 1052 on the body 1051 is greater than or equal to an area of the first beam spot, and an area of an orthogonal projection of the second convex lens 1053 on the body 1051 is greater than or equal to the area of the first beam spot. For example, one first convex lens 1052 and one second convex lens 1053 corresponding to the one first convex lens 1052 may be referred to as a group of light homogenizing convex lenses. In a case where the first beam spot of one first laser beam overlaps with an orthogonal projection of one group of light homogenizing convex lenses on the body 1051, one first convex lens 1052 and one second convex lens 1053 may achieve the homogenization of the first laser beam. In this way, the numbers of the first convex lenses 1052 and the second convex lenses 1053 in the light homogenizing component 105 may be reduced, thereby simplifying the structure of the light homogenizing component 105.

It will be noted that the present disclosure does not limit whether the first beam spot of the first laser beam overlaps with the orthogonal projection of a certain group of light homogenizing convex lenses on the body 1051. Since the first laser beam is transmitted to the light homogenizing component 105 after being collimated into the parallel beam by the first collimating portion 104, even if the first beam spot of the first laser beam does not overlap with the orthogonal projection of a certain group of light homogenizing convex lenses on the body 1051, the first laser beam may also be homogenized by the light homogenizing component 105.

In some embodiments, referring to FIG. 10, the first reflecting portion 103 includes a first reflecting surface 1031, and the first reflecting surface 1031 is a concave curved surface. The first collimating portion 104 includes the first reflecting surface 1031. For example, after being transmitted to the concave curved surface, the laser beam with a divergence angle may be converged to become the parallel beam by the concave curved surface.

The first reflecting surface 1031 is a surface of the first reflecting portion 103 facing the first light-emitting chip 102 and is configured to direct the first laser beam to the direction away from the base plate 1011.

In some embodiments, the entire first reflecting surface 1031 may be the concave curved surface. Alternatively, a portion of the first reflecting surface 1031 may be the concave curved surface, as long as the first laser beam emitted by the first light-emitting chip 102 may be incident onto the concave curved surface of the corresponding first reflecting portion 103.

It will be noted that a curvature of the concave curved surface is less than or equal to a target curvature. The greater the curvature of the concave curved surface, the closer a reflection direction of the incident laser beam reflected by the concave curved surface is to an incident direction of the incident laser beam. However, in some embodiments of the present disclosure, the concave curved surface is required to reflect the incident laser beam in the direction (e.g., the direction Z in FIG. 10) away from the base plate 1011. Therefore, it is necessary to prevent the curvature of the concave curved surface from being too large, so as to avoid a large difference between the reflection direction of the laser beam and the direction Z.

In the related art, referring to FIG. 11, a laser device 10A includes a base plate 1011A, a frame 1012A, a plurality of light-emitting chips 102A, a plurality of reflecting prisms 103E, and a collimating lens group 104A. The collimating lens group 104A is disposed on a side of the frame 1012A away from the base plate 1011A. The collimating lens group 104A includes a plurality of collimating lenses 1041A. One light-emitting chip 102A corresponds to one reflecting prism 103E and one collimating lens 1041A. A laser beam emitted by one light-emitting chip 102A may be reflected to the collimating lens group 104A by the corresponding reflecting prism 103E and then exit from the laser device 10 after being collimated by the corresponding collimating lens 1041A, so as to form the illumination beams.

Compared with the above related art, the first reflecting surface 1031 of the first reflecting portion 103 is provided as the concave curved surface in the some embodiments of the present disclosure. Referring to FIG. 10, when a plurality of sub-beams L1, L2, and L3 in the first laser beam are reflected by the concave curved surface, the concave curved surface converges the plurality of sub-beams, so that propagation directions of the plurality of sub-beams may be substantially the same. Therefore, the first laser beam with a divergence angle emitted by the first light-emitting chip 102 may be collimated into a parallel beam after being reflected by the concave curved surface. In this way, there is no need to provide the collimating lens group 104A in the laser device 10, thereby reducing the number of components in the laser device 10 and facilitating the miniaturization design of the laser device 10.

Of course, the first collimating portion 104 may also be of other structures to collimate the first laser beam.

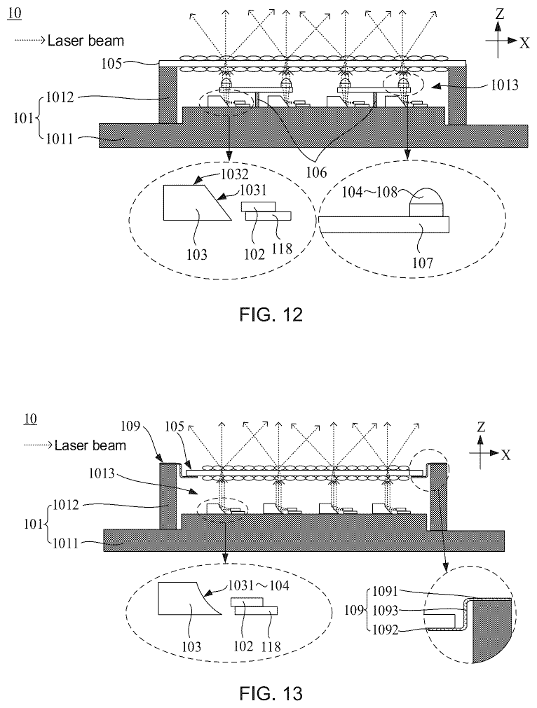

In some other embodiments, referring to FIG. 12, the laser device 10 further includes a first collimating lens 108 located on a laser-exit side of the first reflecting portion 103. The first collimating portion 104 includes the first collimating lens 108.

The first reflecting portion 103 includes a supporting surface 1032. The supporting surface 1032 is a surface of the first reflecting portion 103 away from the base plate 1011 and may be substantially parallel to the base plate 1011. The laser device 10 further includes a first mounting member 106 and a second mounting member 107. The first mounting member 106 is disposed on one of the base plate 1011 and the supporting surface 1032 and located in the sealed space 1013. It will be noted that FIG. 12 is illustrated by considering an example in which the first mounting member 106 is disposed on the base plate 1011. The second mounting member 107 is disposed on a side of the first mounting member 106 away from the base plate 1011, and the first collimating lens 108 is disposed on a side of the second mounting member 107 away from the base plate 1011.

In this way, by arranging the first collimating lens 108 in the sealed space 1013, an optical path of the first laser beam transmitted to the first collimating lens 108 is shortened, thereby reducing an area of a beam spot formed by the first laser beam on the first collimating lens 108. Generally, it is required that an area of an orthogonal projection of the first collimating lens 108 on the base plate 1011 is greater than the area of the beam spot formed by the first laser beam on the first collimating lens 108, so that the first collimating lens 108 may collimate a lot of sub-beams in the first laser beam. However, in some embodiments of the present disclosure, by reducing the area of the beam spot formed by the first laser beam on the first collimating lens 108, it is possible to reduce a required volume of the first collimating lens 108 for collimating the first laser beam, thereby reducing the volume of the laser device 10, which is conducive to the miniaturization of the laser device 10.

The arrangement manner of the light homogenizing component 105 in the laser device 10 is introduced below with reference to the accompanying drawings.

In some embodiments, referring to FIG. 10, an edge of the light homogenizing component 105 is fixed to a side of the frame 1012 away from the base plate 1011, and the sealed space 1013 is defined between the light homogenizing component 105, the frame 1012, and the base plate 1011, so that the first light-emitting chip 102 may be located in the closed sealed space 1013, which may prevent water and oxygen from corroding the first light-emitting chip 102.

It will be noted that the edge of the light homogenizing component 105 may not be provided with the first convex lens 1052 or the second convex lens 1053. In this way, the light homogenizing component 105 may be fixed to the side of the frame 1012 away from the base plate 1011 through the body 1051. The body 1051 is relatively flat, which may improve the fixing effect between the edge of the light homogenizing component 105 and the frame 1012.

In some other embodiments, as shown in FIG. 13, the laser device 10 further includes a cover plate 109 in an annular shape. An outer edge of the cover plate 109 is fixed to the side of the frame 1012 away from the base plate 1011. For example, as shown in FIG. 13, the cover plate 109 includes an outer edge portion 1091, an inner edge portion 1092, and a bending portion 1093. The bending portion 1093 is located between the outer edge portion 1091 and the inner edge portion 1092. The inner edge portion 1092 is recessed toward the base plate 1011, and the outer edge portion 1091 is fixed on a surface of the frame 1012 away from the base plate 1011. The light homogenizing component 105 is located on a side of the inner edge portion 1092 away from the base plate 1011, and the edge of the light homogenizing component 105 is fixedly connected to the inner edge portion 1092.

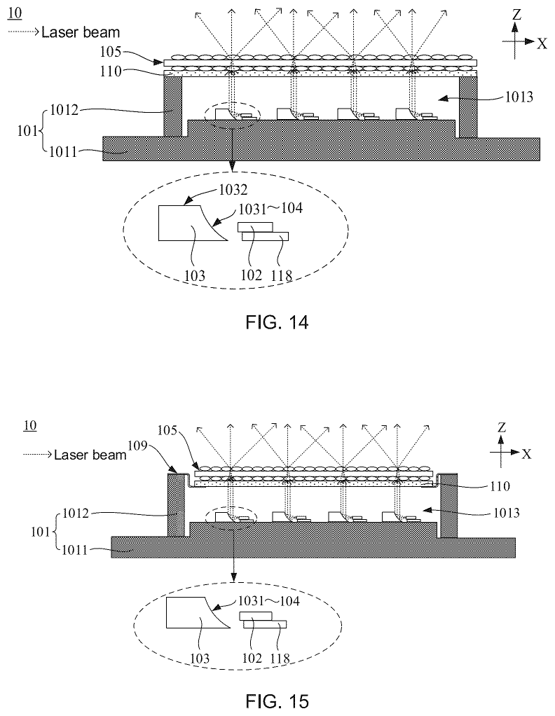

In yet some other embodiments, as shown in FIG. 14, the laser device 10 further includes a light-transmitting layer 110, and the light homogenizing component 105 is located on a side of the light-transmitting layer 110 away from the base plate 1011.

In some examples, as shown in FIG. 14, an edge of the light-transmitting layer 110 is fixed to the side of the frame 1012 away from the base plate 1011.

In some other examples, as shown in FIG. 15, in a case where the laser device 10 includes the cover plate 109, the outer edge portion 1091 of the cover plate 109 is fixed to the side of the frame 1012 away from the base plate 1011, and the edge of the light-transmitting layer 110 is fixed to the inner edge portion 1092 of the cover plate 109. Here, for the outer edge portion 1091 and the inner edge portion 1092 of the cover plate 109, reference may be made to the structure of the cover plate 109 shown in FIG. 13.

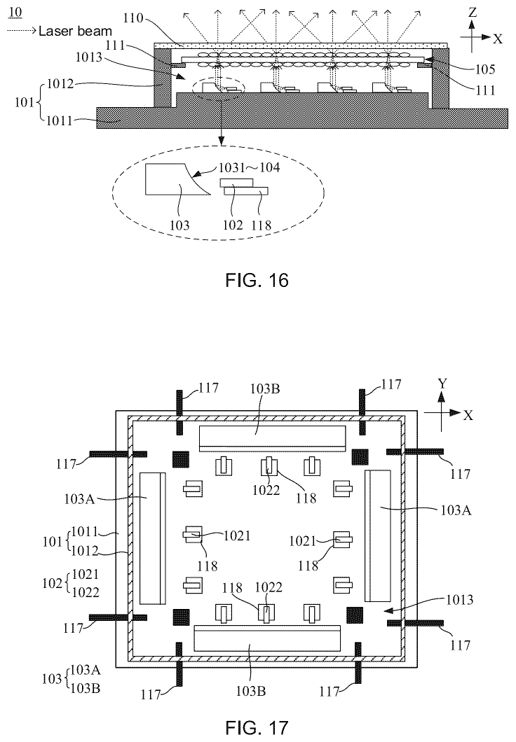

In yet some other embodiments, as shown in FIG. 16, the laser device 10 further includes a boss 111 located in the sealed space 1013, and an outer edge of the boss 111 is fixed to the frame 1012, and an inner edge of the boss 111 is fixed to the outer edge of the light homogenizing component 105. The light homogenizing component 105 is disposed on a side of the boss 111 away from the base plate 1011.

It will be noted that the boss 111 may be a one-piece member or include a plurality of sub-bosses. For example, in a case where the boss 111 is a one-piece member, the boss is an annular boss. In this case, the light homogenizing component 105 may be firmly disposed on the boss 111. Alternatively, in a case where the boss 111 includes a plurality of sub-bosses, the frame 1012 is provided with the plurality of sub-bosses 111 at intervals. In this case, space occupied by the boss 111 in the sealed space 1013 is small, which is conducive to the miniaturization of the laser device 10.

In a case where the laser device 10 includes the boss 111, the side of the frame 1012 away from the base plate 1011 may be fixedly connected with one of the light-transmitting layer 110 and the cover plate 109. For example, in a case where the side of the frame 1012 away from the base plate 1011 is fixedly connected with the outer edge portion 1091 of the cover plate 109, the inner edge portion 1092 of the cover plate 109 may be fixedly connected to the light-transmitting layer 110.

In some embodiments, as shown in FIG. 17, the plurality of first light-emitting chips 102 include a first type light-emitting chip 1021 and a second type light-emitting chip 1022. The first type light-emitting chip 1021 is configured to emit a first type laser beam in the first laser beam, and the second type light-emitting chip 1022 is configured to emit a second type laser beam in the first laser beam. A polarization direction of the first type laser beam is perpendicular to a polarization direction of the second type laser beam. For example, the first type laser beam may be a P-polarized light, such as a red laser beam; and the second type laser beam may be an S-polarized light, such as at least one of a green laser beam or a blue laser beam.

In this case, a laser-exit direction of the first type light-emitting chip 1021 is parallel to a first direction X, a laser-exit direction of the second type light-emitting chip 1022 is parallel to a second direction Y, and the first direction X is perpendicular to the second direction Y. Moreover, the first direction X and the second direction Y may be parallel to the base plate 1011.

Laser beams with different polarization directions have different transmittance when passing through other optical components (e.g., the projection lens 3) in the laser projection apparatus 1000. Therefore, if the illumination beams provided by the laser device 10 include the laser beams with a plurality of polarization directions, color spots and color blocks may appear in the displayed projection image after the illumination beams are modulated by the light modulation assembly 2 and projected by the projection lens 3, as a result, the display effect may be affected. In some embodiments of the present disclosure, since the polarization direction of the first type laser beam is perpendicular to the polarization direction of the second type laser beam, by providing the laser-exit direction of the first type light-emitting chip 1021 to be perpendicular to the laser-exit direction of the second type light-emitting chip 1022, it is possible to make the first type laser beam and the second type laser beam have a same polarization direction after the first type laser beam and the second type laser beam are guided to the direction away from the base plate 1011 by the first reflecting portion 103. In this way, the polarization directions of the first laser beam in the illumination beams exiting from the laser device 10 may be consistent, so that the transmittance of the illumination beams passing through the optical components may be consistent, thereby avoiding the occurrence of color spots and color blocks in the projection image projected by the laser projection apparatus 1000 and improving the display effect of the projection image.

In some embodiments, as shown in FIG. 18, the laser device 10 includes a plurality of first type light-emitting chips 1021 and a plurality of second type light-emitting chips 1022. The plurality of first type light-emitting chips 1021 are arranged in a plurality of rows in the first direction X, the plurality of rows of first type light-emitting chips 1021 are arranged alternately, and each row of first type light-emitting chips 1021 are arranged in the second direction Y. The plurality of second type light-emitting chips 1022 are arranged in a plurality of rows in the second direction Y, the plurality of rows of second type light-emitting chips 1022 are arranged alternately, and each row of second type light-emitting chips 1022 are arranged in the first direction X.

In this way, in an aspect, a lot of first type light-emitting chips 1021 and second type light-emitting chips 1022 may be arranged in the laser device 10 without increasing the size of the laser device 10, thereby improving the luminance of the laser device 10. In another aspect, in a case where a distance between two adjacent rows of first type light-emitting chips 1021 is constant, by providing the plurality of rows of first type light-emitting chips 1021 arranged alternately, it is possible to increase a distance between a first type light-emitting chip 1021 and a first type light-emitting chip adjacent to the first type light-emitting chip 1021 and located in a different row, which is conducive to improving the heat dissipation efficiency of the first type light-emitting chips 1021. Similarly, by providing the plurality of rows of second type light-emitting chips 1022 arranged alternately, it is conducive to improving the heat dissipation efficiency of the second type light-emitting chips 1022.

It will be noted that two rows of first type light-emitting chips 1021 are arranged alternately, which means that the first type light-emitting chips 1021 in the two rows are located at different positions in the second direction Y. That is to say, at least one first type light-emitting chip 1021 in a row of first type light-emitting chips 1021 is unaligned in the second direction Y with the first type light-emitting chips 1021 in another row of first type light-emitting chips 1021. Similarly, two rows of second type light-emitting chips 1022 are arranged alternately, which means that the second type light-emitting chips 1022 in the two rows are misaligned in the first direction X. That is to say, at least one second type light-emitting chip 1022 in a row of second type light-emitting chips 1022 is unaligned in the first direction X with the second type light-emitting chips 1022 in another row of second type light-emitting chips 1022.

In addition, the plurality of rows of first type light-emitting chips 1021 are arranged alternately, which means that at least two rows of first type light-emitting chips 1021 are arranged alternately in the plurality rows of first type light-emitting chips 1021. Similarly, the plurality of rows of second type light-emitting chips 1022 are arranged alternately, which means that at least two rows of second type light-emitting chips 1022 are arranged alternately in the plurality rows of second type light-emitting chips 1022.

In some embodiments, as shown in FIG. 18, in a case where the laser device 10 includes the plurality of second type light-emitting chips 1022, the plurality of second type light-emitting chips 1022 include a first light-emitting sub-chip 10221 and a second light-emitting sub-chip 10222.

For example, the first light-emitting sub-chip 10221 is configured to emit a first laser sub-beam of the second type laser beam, such as a green laser beam; and the second light-emitting sub-chip 10222 is configured to emit a second laser sub-beam of the second type laser beam, such as a blue laser beam. Of course, the first light-emitting sub-chip 10221 and the second light-emitting sub-chip 10222 may also emit laser beams of other colors, and the present disclosure is not limited thereto.

A laser-exit direction of the first light-emitting sub-chip 10221 is perpendicular to a laser-exit direction of the second light-emitting sub-chip 10222. As shown in FIG. 18, the laser-exit direction of the first light-emitting sub-chip 10221 is the second direction Y, and the first light-emitting sub-chip 10221 may also be referred to as a second type light-emitting chip 1022 with positive arrangement. The laser-exit direction of the second light-emitting sub-chip 10222 is opposite to the second direction Y, and the second light-emitting sub-chip 10222 may also be referred to as a second type light-emitting chip 1022 with negative arrangement.

In this way, since the first laser sub-beam emitted by the first light-emitting sub-chip 10221 and the second laser sub-beam emitted by the second light-emitting sub-chip 10222 do not intersect with each other, it is possible to avoid mutual interference between the first laser sub-beam and the second laser sub-beam, thereby improving the quality of the illumination beams provided by the laser device 10. Of course, the laser-exit direction of the first light-emitting sub-chip 10221 may also be the opposite direction of the second direction Y, and the laser-exit direction of the second light-emitting sub-chip 10222 is the second direction Y. That is to say, the first light-emitting sub-chip 10221 and the second light-emitting sub-chip 10222 each emit the laser beam toward a central region of the base plate 1011.

The arrangement manner of the first reflecting portion 103 is introduced below with reference to the accompanying drawings.

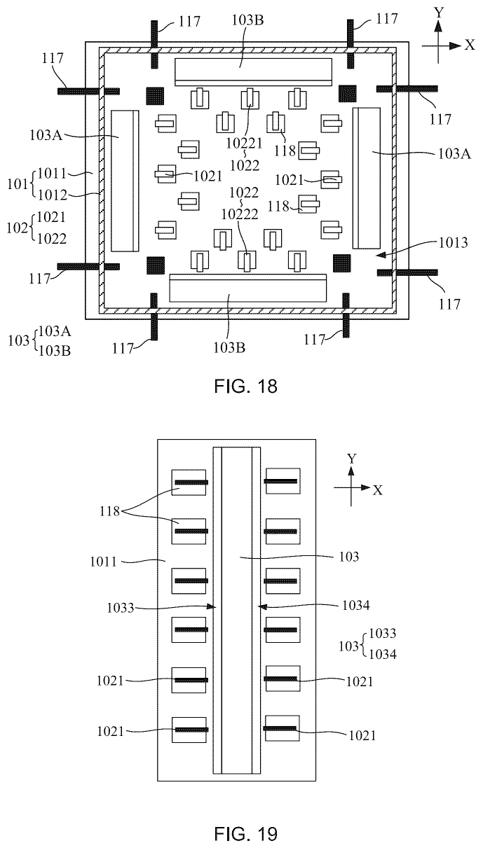

In some embodiments, in a case where the laser device 10 includes a plurality of first type light-emitting chips 1021, the first reflecting portion 103 may be a one-piece member. As shown in FIG. 19, the first reflecting portion 103 includes a first surface 1033 and a second surface 1034 that are arranged opposite to each other in the first direction X.

The first surface 1033 (or the second surface 1034) corresponds to at least one first type light-emitting chip 1021 in the plurality of first type light-emitting chips 1021 and is configured to guide the first type laser beam emitted by the corresponding at least one first type light-emitting chip 1021 to the direction away from the base plate 1011.

Since the plurality of first type light-emitting chips 1021 are located on two opposite sides of the first reflecting portion 103, two or more first type light-emitting chips 1021 corresponding to the first surface 1033 and two or more first type light-emitting chips 1021 corresponding to the second surface 1034 are arranged at an interval, so as to facilitate the heat dissipation of the first type light-emitting chips 1021.

In some embodiments, the first surface 1033 and the second surface 1034 are concave curved surfaces or planes. For example, in a case where the first surface 1033 and the second surface 1034 are concave curved surfaces, the first surface 1033 and the second surface 1034 each may collimate the first type laser beam emitted by the corresponding at least one first type light-emitting chip 1021. In this case, the first collimating portion 104 includes the first surface 1033 and the second surface 1034. Alternatively, in a case where the first surface 1033 and the second surface 1034 are planes, the first surface 1033 and the second surface 1034 may not collimate the first type laser beam. In this case, the first collimating portion 104 may include the above first collimating lens 108.

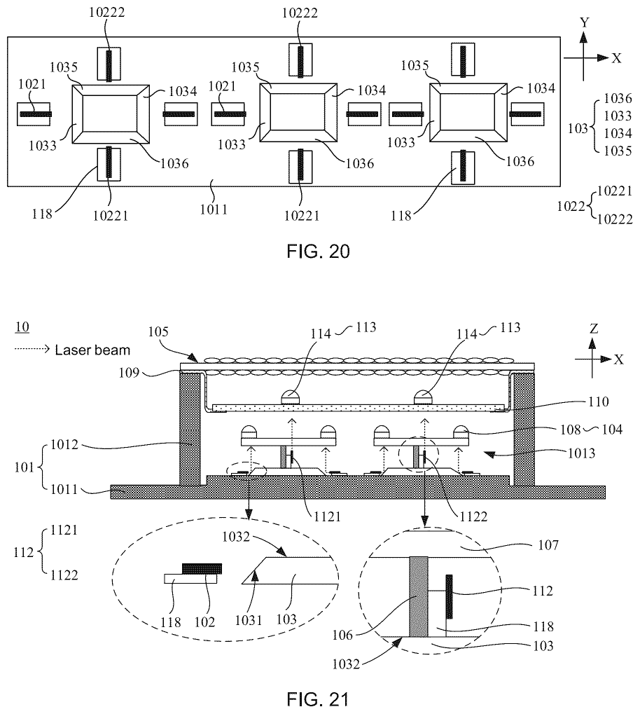

In some embodiments, in a case where the laser device 10 further includes the plurality of second type light-emitting chips 1022, as shown in FIG. 20, the first reflecting portion 103 further includes a third surface 1035 and a fourth surface 1036 that are arranged opposite to each other in the second direction Y.

The third surface 1035 (or the fourth surface 1036) corresponds to at least one second type light-emitting chip 1022 in the plurality of second type light-emitting chips 1022 and is configured to guide the second type laser beam emitted by the corresponding at least one second type light-emitting chip 1022 to the direction away from the base plate 1011.

In this case, as shown in FIG. 20, since four light-emitting chips are disposed around the first reflecting portion 103, an interval between any adjacent two light-emitting chips in the four light-emitting chips is large, so that the heat dissipation of the first light-emitting chips 102 may be facilitated.

In some embodiments, the third surface 1035 and the fourth surface 1036 are concave curved surfaces or planes. For example, in a case where the third surface 1035 and the fourth surface 1036 are concave curved surfaces, the third surface 1035 and the fourth surface 1036 each may collimate the second type laser beam emitted by the corresponding at least one second type light-emitting chip 1022. In this case, the first collimating portion 104 includes the third surface 1035 and the fourth surface 1036. Alternatively, in a case where the third surface 1035 and the fourth surface 1036 are planes, the third surface 1035 and the fourth surface 1036 may not collimate the second type laser beam. In this case, the first collimating portion 104 may include the above first collimating lens 108.

In some embodiments, in a case where the laser device 10 includes the first type light-emitting chip 1021 and the second type light-emitting chip 1022, the first reflecting portion 103 may be separate piece members. As shown in FIGS. 17 and 18, the first reflecting portion 103 includes a first reflecting sub-portion 103A and a second reflecting sub-portion 103B. The first reflecting sub-portion 103A is disposed on a laser-exit side of the first type light-emitting chip 1021 and configured to guide the first type laser beam emitted by the first type light-emitting chip 1021 to the direction away from the base plate 1011. The second reflecting sub-portion 103B is disposed on a laser-exit side of the second type light-emitting chip 1022 and configured to guide the second type laser beam emitted by the second type light-emitting chip 1022 to the direction away from the base plate 1011.

In this way, the first type laser beam and the second type laser beam may be guided to the direction away from the base plate 1011 by the first reflecting sub-portion 103A and the second reflecting sub-portion 103B, respectively, so as to avoid the mutual interference between the first type laser beam and the second type laser beam, thereby improving the quality of the illumination beams provided by the laser device 10.

It will be noted that, FIGS. 17 and 18 are illustrated by considering an example in which one first reflecting sub-portion 103A corresponds to a plurality of first type light-emitting chips 1021, and one second reflecting sub-portion 103B corresponds to a plurality of second type light-emitting chips 1022. Of course, the present disclosure does not limit the number of first type light-emitting chips 1021 corresponding to one first reflecting sub-portion 103A or the number of second type light-emitting chips 1022 corresponding to one second reflecting sub-portion 103B. For example, the laser device 10 shown in FIG. 17 includes two first reflecting sub-portions 103A arranged corresponding to six first type light-emitting chips 1021. Alternatively, the laser device 10 shown in FIG. 18 includes two first reflecting sub-portions 103A arranged corresponding to ten first type light-emitting chips 1021.

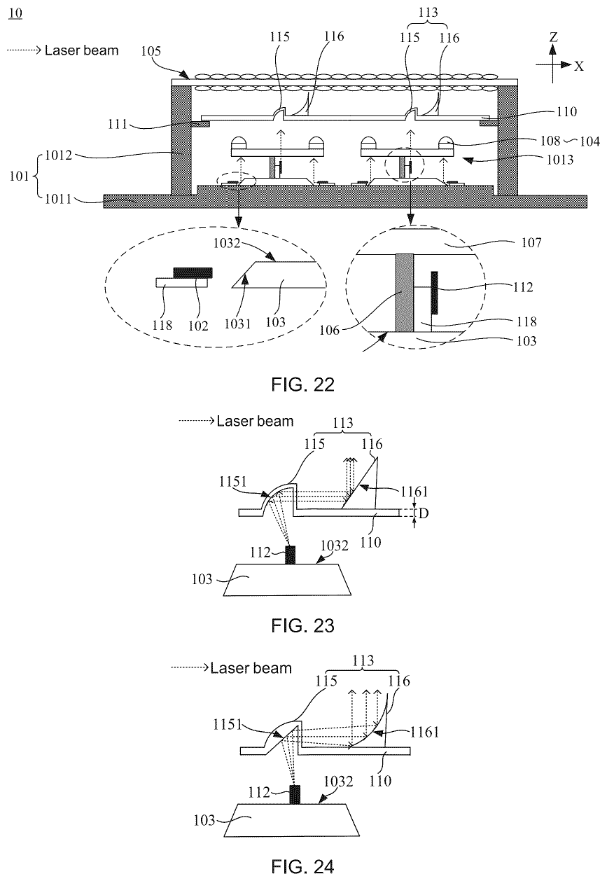

In some embodiments, as shown in FIGS. 21 and 22, in addition to the above tube shell 101, the first light-emitting chips 102, the first reflecting portions 103, the homogenizing component 105, and the light-transmitting layer 110, the laser device 10 further includes a second light-emitting chip 112 and a second collimating portion 113.

The second light-emitting chip 112 is disposed on one of the base plate 1011 and the supporting surface 1032 and located in the sealed space 1013. The second light-emitting chip 112 is configured to emit a second laser beam, and a laser-exit direction of the second light-emitting chip 112 is perpendicular to the base plate 1011. It will be noted that, FIGS. 21 and 22 are illustrated by considering an example in which the second light-emitting chip 112 is disposed on the supporting surface 1032. In some embodiments, the laser device 10 may include a plurality of second light-emitting chips 112.

The light-transmitting layer 110 is located in the sealed space 1013 and disposed on a laser-exit side of the second light-emitting chip 112.

The second collimating portion 113 is located in the sealed space 1013 and disposed on a side of the light-transmitting layer 110 away from the base plate 1011 and is located on the laser-exit side of the second light-emitting chip 112. The second collimating portion 113 is configured to collimate the second laser beam and transmit the second laser beam to the light homogenizing component 105.

The light homogenizing component 105 is further configured to homogenize the second laser beam, and the second laser beam may exit from the sealed space 1013, so that the second laser beam together with the first laser beam may form the illumination beams.

In this way, more light-emitting chips may be arranged in the laser device 10 without increasing the size of the laser device 10, thereby improving the luminance of the laser device 10 and facilitating the miniaturization of the laser device 10. In addition, in a case where the second light-emitting chip 112 is disposed on the supporting surface 1032, the first light-emitting chip 102 and the second light-emitting chip 112 are arranged in different planes in the laser device 10. Therefore, heat dissipation regions of the first light-emitting chip 102 and the second light-emitting chip 112 do not overlap with each other. In this way, the heat dissipation efficiency of the laser device 10 is improved, so that the laser device 10 may have the characteristics of high luminance, small volume and high heat dissipation efficiency.

In some embodiments, as shown in FIG. 21, in a case where the laser device 10 includes the above first mounting member 106, the second light-emitting chip 112 is connected to the first mounting member 106. In this way, the second light-emitting chip 112 may be stably installed, and the heat generated by the second light-emitting chip 112 during operation may be conducted to the first reflecting portion 103 and the base plate 1011 through the first mounting member 106, thereby improving the heat dissipation efficiency of the second light-emitting chip 112.

In some embodiments, an optical path of the first laser beam transmitted from the first light-emitting chip 102 to the first collimating portion 104 is equal to an optical path of the second laser beam transmitted from the second light-emitting chip 112 to the second collimating portion 113.

In this way, the shape and size of the beam spot of the first laser beam collimated by the first collimating portion 104 may be consistent with a shape and size of a beam spot of the second laser beam collimated by the second collimating portion 113, so that the consistency of the first laser beam and the second laser beam in the illumination beams provided by laser device 10 may be improved, thereby improving the quality of the illumination beams.

It will be noted that, in some embodiments of the present disclosure, a distance between the light-transmitting layer 110 and the base plate 1011 is less than a distance between the light homogenizing component 105 and the base plate 1011. The present disclosure does not limit the arrangement manner of the light-transmitting layer 110 and the light homogenizing component 105.

For example, as shown in FIG. 21, the laser device 10 further includes the above cover plate 109. The edge of the light-transmitting layer 110 is fixed to the inner edge portion 1092 of the cover plate 109, and the edge of the light homogenizing component 105 is fixed to a side of the outer edge portion 1091 away from the frame 1012.

Alternatively, as shown in FIG. 22, the laser device 10 further includes the above boss 111, the edge of the light-transmitting layer 110 is fixed to an inner edge of the boss 111, and the edge of the light homogenizing component 105 is fixed to the side of the frame 1012 away from the base plate 1011.

Alternatively, the laser device 10 further includes the above cover plate 109 and the boss 111, and a distance between the boss 111 and the base plate 1011 is less than a minimum distance between the cover plate 109 and the base plate 1011. In this way, the edge of the light-transmitting layer 110 may be fixed to the inner edge of the boss 111, and the edge of the light homogenizing component 105 may be fixed to the inner edge portion 1092 of the cover plate 109.

A structure of the second collimating portion 113 is described below with reference to the accompanying drawings.

In some embodiments, as shown in FIG. 21, the second collimating portion 113 includes a second collimating lens 114.

For example, the second collimating lens 114 is a plane-convex lens, and a plane of the plane-convex lens faces the base plate 1011, and a convex surface of the plane-convex lens faces the light homogenizing component 105. In this way, the second collimating lens 114 may be fixed with the light-transmitting layer 110 through the plane, so that the second collimating lens 114 may be stably disposed. Moreover, the second collimating lens 114 may collimate the second laser beam into a parallel beam, so as to facilitate light homogenization of the light homogenizing component 105 on the second laser beam, thereby improving the quality of the illumination beams provided by the laser device 10.

It will be noted that, FIG. 21 is illustrated by considering an example in which the first collimating portion 104 includes the first collimating lens 108. Of course, the first collimating portion 104 may also include the first reflecting surface 1031, and the first reflecting surface 1031 is the concave curved surface.

In some other embodiments, as shown in FIG. 22, the second collimating portion 113 includes a second reflecting portion 115 and a third reflecting portion 116.

The second reflecting portion 115 is located on the laser-exit side of the second light-emitting chip 112 and configured to guide the second laser beam to a direction parallel to the base plate 1011. The third reflecting portion 116 is located on a laser-exit side of the second reflecting portion 115 and configured to guide the incident second laser beam to the direction away from the base plate 1011, so as to transmit the second laser beam to the light homogenizing component 105.

One of the second reflecting portion 115 and the third reflecting portion 116 is further configured to collimate the second laser beam.

In some examples, as shown in FIG. 23, the second reflecting portion 115 has a second reflecting surface 1151, and the second reflecting surface 1151 is a surface of the second reflecting portion 115 facing the second light-emitting chip 112. The third reflecting portion 116 has a third reflecting surface 1161, and the third reflecting surface 1161 is a surface of the third reflecting portion 116 facing the second reflecting surface 1151. The second reflecting surface 1151 is a concave curved surface and configured to collimate the second laser beam and reflect the second laser beam in the direction parallel to the base plate 1011. The third reflecting surface 1161 is a plane and configured to reflect the second laser beam in the direction away from the base plate 1011.

In some other examples, as shown in FIG. 24, the second reflecting portion 115 has a second reflecting surface 1151, and the second reflecting surface 1151 is a surface of the second reflecting portion 115 facing the second light-emitting chip 112. The third reflecting portion 116 has a third reflecting surface 1161, and the third reflecting surface 1161 is a surface of the third reflecting portion 116 facing the second reflecting surface 1151. The second reflecting surface 1151 is a plane and configured to reflect the second laser beam in the direction parallel to the base plate 1011. The third reflecting surface 1161 is a concave curved surface and configured to collimate the second laser beam and reflect the second laser beam in the direction away from the base plate 1011.

It will be noted that, in some embodiments of the present disclosure, the first laser beam is incident onto the light-transmitting layer 110 and forms a second beam spot on the light-transmitting layer 110. An orthogonal projection of the second collimating portion 113 on the light-transmitting layer 110 does not overlap with the second beam spot (that is, an orthogonal projection of the second collimating portion 113 on the light-transmitting layer 110 is outside the second beam spot). In this way, the second collimating portion 113 may not interfere with the first laser beam, so as to improve the utilization rate of the first laser beam in the laser device 10, and thereby improving the light-emitting efficiency of the laser device 10. In an example where the second collimating portion 113 includes the second reflecting portion 115 and the third reflecting portion 116, after the first laser beam is transmitted to the light-transmitting layer 110, the first laser beam may pass through the light-transmitting layer 110 and reach the light homogenizing component 105 without being reflected to other directions by the second reflecting portion 115 or the third reflecting portion 116.

In some embodiments, as shown in FIG. 21, the plurality of second light-emitting chips 112 include a third type light-emitting chip 1121 (e.g., a first portion of light-emitting chips) and a fourth type light-emitting chip 1122 (e.g., a second portion of light-emitting chips). The third type light-emitting chip 1121 is configured to emit a first type laser beam in the second laser beam. The fourth type light-emitting chip 1122 is configured to emit a second type laser beam in the second laser beam. A polarization direction of the first type laser beam is perpendicular to a polarization direction of the second type laser beam. As for the relevant content of the first type laser beam and the second type laser beam, reference may be made to the relevant description above, and details will not be repeated herein.

In a case where the laser device 10 includes a second mounting member 107, the second mounting member 107 includes a polarization conversion component configured to change a polarization direction of at least one of the first type laser beam or the second type laser beam, so that the polarization direction of the first type laser beam is the same as that of the second type laser beam.

In some examples, the second mounting member 107 adjusts a polarization direction of a portion of the incident second laser beam. For example, the second mounting member 107 adjusts the polarization direction of the first type laser beam by 90 degrees without adjusting the polarization direction of the second type laser beam. Alternatively, the second mounting member 107 adjusts the polarization direction of the second type laser beam by 90 degrees without adjusting the polarization direction of the first type laser beam. Since the polarization direction of the first type laser beam is perpendicular to the polarization direction of the second type laser beam In this way, the second mounting member 107 may adjust the polarization directions of the incident first type laser beam and second type laser beam to be same. For example, the second mounting member 107 includes a half-wave plate.

In some other examples, the second mounting member 107 adjusts the polarization directions of all incident laser beams. For example, the second mounting member 107 may adjust the polarization direction of the first type laser beam by 45 degrees and adjust the polarization direction of the second type laser beam by 45 degrees. For example, the second mounting member 107 includes a quarter-wave plate.

It will be noted that the adjusted angle of the second mounting member 107 for a polarization direction of a laser beam is related to a thickness D (as shown in FIG. 23) of the second mounting member 107 and a wavelength of the laser beam. For example, in a case where the wavelength of the laser beam is constant, the greater the thickness D of the second mounting member 107, the greater the adjusted angle of the second mounting member 107 for the polarization direction of the laser beam. For example, in a case where the wavelength of the laser beam is constant, a thickness of a half-wave plate is greater than a thickness of a quarter-wave plate.

In addition, in some embodiments, the second mounting member 107 may further include a light-transmitting component, and the light-transmitting component and the polarization conversion component constitute the second mounting member 107. The polarization conversion component may be located in the propagation path of the laser beam whose polarization direction needs to be adjusted, and the light-transmitting component is located in the propagation path of the laser beam without adjustment of the polarization direction. In this way, the first collimating lens 108 may be disposed on a side of the light-transmitting component away from the base plate 1011.

In some embodiments, as shown in FIG. 17, there are a plurality of holes on two opposite sides of the frame 1012, and the laser device 10 further includes a plurality of conductive pins 117. The plurality of conductive pins 117 pass through the plurality of holes in the frame 1012, extend into the sealed space 1013, and are fixed in the plurality of holes. For example, one hole corresponds to one conductive pin 117. The plurality of conductive pins 117 each are configured to be electrically connected to an electrode of at least one of the first light-emitting chip 102 or the second light-emitting chip 112, so as to transmit a current from an external power supply to at least one of the first light-emitting chip 102 or the second light-emitting chip 112, so that power may be supplied to the at least one of the first light-emitting chip 102 or the second light-emitting chip 112.

It will be noted that, in a case where the second light-emitting chip 112 is disposed on the supporting surface 1032, a through hole may be disposed on the supporting surface 1032, and a conductive structure electrically connected to the external power supply may be disposed on the base plate 1011. A wire connected to the conductive structure may be connected to the second light-emitting chip 112 through the through hole, so as to supply power to the second light-emitting chip 112, thereby preventing the wire from blocking the laser beam emitted by at least one of the first light-emitting chip 102 or the second light-emitting chip 112.

In some embodiments, referring to FIG. 10, the laser device 10 further includes a plurality of heat sinks 118 corresponding to the first light-emitting chips 102 or the second light-emitting chips 112. The heat sink 118 is located between the corresponding first light-emitting chip 102 and the base plate 1011, or between the corresponding second light-emitting chip 112 and the base plate 1011, and configured to assist the first light-emitting chip 102 or the second light-emitting chip 112 to dissipate heat, so that the heat generated by the first light-emitting chip 102 or the second light-emitting chip 112 may be rapidly transferred to the base plate 1011. In some embodiments, the plurality of first light-emitting chips 102 or the plurality of second light-emitting chips 112 may share one heat sink 118, and the present disclosure is not limited thereto. It will be noted that, in a case where the second light-emitting chip 112 is disposed on the first mounting member 106, the heat sink 118 may be located between the second light-emitting chip 112 and the first mounting member 106.

To sum up, in the laser projection apparatus 1000 provided in some embodiments of the present disclosure, the laser device 10 is integrated with the light homogenizing component 105, so that the first laser beam emitted by the first light-emitting chip 102 may be homogenized by the light homogenizing component 105 and then exit from the light homogenizing component 105, and the homogenized first laser beam may constitute at least a portion of the illumination beams, thereby improving the uniformity of the illumination beams provided by the laser device 10. In this way, there is no need to additionally arrange a light pipe in the laser source assembly 1, so as to homogenize the illumination beams filtered by the optical filter portion 13, thereby reducing the number of components in the laser source assembly 1 and facilitating miniaturization of the laser projection apparatus 1000. In addition, by adjusting the arrangement manner of the first type light-emitting chip 1021 and the second type light-emitting chip 1022 in the first light-emitting chips 102, the polarization directions of the first type laser beam and the second type laser beam may be consistent, so that the transmittance of the illumination beams provided by the laser device 10 passing through the optical components is consistent, thereby improving the display effect of the projection image.

A person skilled in the art will understand that the scope of disclosure in the present disclosure is not limited to specific embodiments discussed above and may modify and substitute some elements of the embodiments without departing from the spirits of the present disclosure. The scope of the present disclosure is limited by the appended claims.

What is claimed is:

1. A laser projection apparatus, comprising:
a laser source assembly configured to provide illumination beams;
a light modulation assembly configured to modulate the illumination beams with an image signal, so as to obtain projection beams; and
a projection lens configured to project the projection beams into an image;
wherein the laser source assembly includes a laser device, and the laser device includes:
a base plate;
a frame disposed on the base plate, a sealed space being defined between the frame, the base plate, and a light homogenizing component;
at least one first light-emitting chip disposed on the base plate and located in the sealed space, the first light-emitting chip being configured to emit a first laser beam; a laser-exit direction of the first light-emitting chip being parallel to the base plate;
a first reflecting portion disposed on the base plate and located in the sealed space, the first reflecting portion being located on a laser-exit side of the first light-emitting chip and configured to guide the first laser beam to a direction away from the base plate;
a first collimating portion located in the sealed space, the first collimating portion being configured to collimate the first laser beam, so as to transmit the first laser beam to the light homogenizing component in a direction perpendicular to the base plate; and
the light homogenizing component disposed on a side of the frame away from the base plate, the light homogenizing component being configured to homogenize the first laser beam and propagate the first laser beam out of the sealed space, so that the first laser beam constitutes at least a part of the illumination beams; the light homogenizing component including:
a body;
a first convex lens located on a side of the body proximate to the base plate: and
a second convex lens located on a side of the body away from the base plate and disposed opposite to the first convex lens:
wherein an area of orthogonal projection of any one of the first convex lens and the second convex lens on the body is greater than or equal to an area of a first beam spot of the first laser beam on the light homogenizing component.

2. The laser projection apparatus according to claim 1, wherein the first reflecting portion includes a first reflecting surface configured to guide the first laser beam to the direction away from the base plate;
wherein the first reflecting surface is a surface of the first reflecting portion facing the first light-emitting chip; and
the first reflecting surface is a concave curved surface, and the first collimating portion includes the first reflecting surface.

3. The laser projection apparatus according to claim 1, wherein the first reflecting portion includes a supporting surface; and the supporting surface is a surface of the first reflecting portion away from the base plate; the laser device further includes:
a first mounting member disposed on one of the base plate and the supporting surface;
a second mounting member disposed on a side of the first mounting member away from the base plate; and
a first collimating lens disposed on a side of the second mounting member away from the base plate and located on a laser-exit side of the first reflecting portion; wherein the first collimating portion includes the first collimating lens.

4. The laser projection apparatus according to claim 3, wherein the laser device further includes at least one second light-emitting chip disposed on the first mounting member and located on the supporting surface, a laser-exit direction of the second light-emitting chip is perpendicular to the base plate, and the second light-emitting chip is configured to emit a second laser beam; and
the light homogenizing component is further configured to homogenize the second laser beam and propagate the second laser beam out of the sealed space; the second laser beam and the first laser beam constitute the illumination beams.

5. The laser projection apparatus according to claim 4, wherein the at least one second light-emitting chip includes a plurality of second light-emitting chips, the plurality of second light-emitting chips include:
a first portion of light-emitting chips configured to emit a first type laser beam in the second laser beam; and
a second portion of the light-emitting chips configured to emit a second type laser beam in the second laser beam;
wherein a polarization direction of the first type laser beam is perpendicular to a polarization direction of the second type laser beam; and
the second mounting member includes a polarization conversion component configured to change the polarization direction of at least one of the first type laser beam or the second type laser beam, so that the polarization direction of the first type laser beam is same as the polarization direction of the second type laser beam.

6. The laser projection apparatus according to claim 4, wherein the laser device further includes:
a light-transmitting layer located in the sealed space and disposed on a laser-exit side of the second light-emitting chip; and
a second collimating portion disposed on a side of the light-transmitting layer away from the base plate, the second collimating portion being configured to collimate the second laser beam and transmit the second laser beam to the light homogenizing component in the direction perpendicular to the base plate.

7. The laser projection apparatus according to claim 6, wherein an optical path of the first laser beam transmitted from the first light-emitting chip to the first collimating portion is equal to an optical path of the second laser beam transmitted from the second light-emitting chip to the second collimating portion.

8. The laser projection apparatus according to claim 6, wherein the second collimating portion includes a second collimating lens located on the laser-exit side of the second light-emitting chip.

9. The laser projection apparatus according to claim 6, wherein the second collimating portion includes:
a second reflecting portion located on the laser-exit side of the second light-emitting chip, and the second reflecting portion being configured to guide the second laser beam to a direction parallel to the base plate; and
a third reflecting portion located on a laser-exit side of the second reflecting portion, and the third reflecting portion being configured to guide the second laser beam incident on the third reflecting portion to the direction away from the base plate, so as to transmit the second laser beam to the light homogenizing component;
wherein one of the second reflecting portion and the third reflecting portion is further configured to collimate the second laser beam.

10. The laser projection apparatus according to claim 9, wherein
the second reflecting portion has a second reflecting surface, the second reflecting surface is a surface of the second reflecting portion facing the second light-emitting chip, and the second reflecting surface is a concave curved surface and configured to collimate the second laser beam and reflect the second laser beam in the direction parallel to the base plate; and
the third reflecting portion has a third reflecting surface, the third reflecting surface is a surface of the third reflecting portion facing the second reflecting surface; and the third reflecting surface is a plane and configured to reflect the second laser beam in the direction away from the base plate.

11. The laser projection apparatus according to claim 9, wherein
the second reflecting portion has a second reflecting surface, the second reflecting surface is a surface of the second reflecting portion facing the second light-emitting chip, and the second reflecting surface is a plane and configured to reflect the second laser beam in the direction parallel to the base plate; and
the third reflecting portion has a third reflecting surface, the third reflecting surface is a surface of the third reflecting portion facing the second reflecting surface, and the third reflecting surface is a concave curved surface and configured to collimate the second laser beam and reflect the second laser beam in the direction away from the base plate.

12. The laser projection apparatus according to claim 6, wherein an orthogonal projection of the second collimating portion on the light-transmitting layer is located outside a second beam spot of the first laser beam on the light-transmitting layer.

13. The laser projection apparatus according to claim 1, wherein an edge of the light homogenizing component is fixed to the side of the frame away from the base plate, the sealed space is defined between the light homogenizing component, the frame, and the base plate.

14. The laser projection apparatus according to claim 1, wherein the laser device satisfies one of followings:
the laser device further includes a cover plate in a shape of an annular, an outer edge portion of the cover plate is fixed to the side of the frame away from the base plate; and an edge of the light homogenizing component is fixed to an inner edge portion of the cover plate;
and
the laser device further includes a light-transmitting layer, an edge of the light-transmitting layer is fixed to the side of the frame away from the base plate; the light homogenizing component is located on a side of the light-transmitting layer away from the base plate;
and
the laser device further includes:
a cover plate in a shape of an annular, an outer edge portion of the cover plate being fixed to the side of the frame away from the base plate; and
a light-transmitting layer, an edge of the light-transmitting layer being fixed to an inner edge portion of the cover plate, and the light homogenizing component being located on a side of the light-transmitting layer away from the base plate;
and
the laser device further includes:
a boss located in the sealed space, an outer edge of the boss being fixed to the frame, and an inner edge of the boss being fixed to an outer edge of the light homogenizing component; and
a light-transmitting layer, an edge of the light-transmitting layer being fixed to the side of the frame away from the base plate; the sealed space being defined between the light-transmitting layer, the frame, and the base plate.

15. The laser projection apparatus according to claim 1, wherein the at least one first light-emitting chip includes a plurality of first light-emitting chips, the plurality of first light-emitting chips include:
at least one first type light-emitting chip configured to emit a first type laser beam in the first laser beam, and a laser-exit direction of the first type light-emitting chip being parallel to a first direction; and
at least one second type light-emitting chip configured to emit a second type laser beam in the first laser beam, and a laser-exit direction of the second type light-emitting chip being parallel to a second direction;
wherein a polarization direction of the first type laser beam is perpendicular to a polarization direction of the second type laser beam, and the first direction is perpendicular to the second direction.

16. The laser projection apparatus according to claim 15, wherein the at least one first type light-emitting chip includes a plurality of first type light-emitting chips, and the at least one second type light-emitting chip includes a plurality of second type light-emitting chips;
the plurality of first type light-emitting chips are arranged in a plurality of rows in the first direction, the plurality of rows of first type light-emitting chips are arranged alternately, and each row of first type light-emitting chips are arranged in the second direction;
the plurality of second type light-emitting chips are arranged in a plurality of rows in the second direction, the plurality of rows of second type light-emitting chips are arranged alternately, and each row of second type light-emitting chips are arranged in the first direction.

17. The laser projection apparatus according to claim 15, wherein the at least one first type light-emitting chip includes a plurality of first type light-emitting chips;
the first reflecting portion includes a first surface and a second surface, and the first surface and the second surface are disposed opposite to each other in the first direction; and
one of the first surface and the second surface corresponds to at least one first type light-emitting chip in the plurality of first type light-emitting chips, and one of the first surface and the second surface is configured to guide the first type laser beam emitted by the corresponding at least one first type light-emitting chip to the direction away from the base plate.

18. The laser projection apparatus according to claim 17, wherein the at least one second type light-emitting chip includes a plurality of second type light-emitting chips;
the first reflecting portion includes a third surface and a fourth surface disposed opposite to each other in the second direction; and
one of the third surface and the fourth surface corresponds to at least one second type light-emitting chip in the plurality of second type light-emitting chips, and one of the third surface and the fourth surface is configured to guide the second type laser beam emitted by the corresponding at least one second type light-emitting chip to the direction away from the base plate.

19. The laser projection apparatus according to claim 15, wherein the at least one second type light-emitting chip includes a plurality of second type light-emitting chips, and the plurality of second type light-emitting chips include a first light-emitting sub-chip and a second light-emitting sub-chip; and
a laser-exit direction of the first light-emitting sub-chip is opposite to a laser-exit direction of the second light-emitting sub-chip.

20. The laser projection apparatus according to claim 15, wherein the first reflecting portion includes:
a first reflecting sub-portion disposed on the laser-exit side of the first type light-emitting chip and configured to guide the first type laser beam to the direction away from the base plate; and
a second reflecting sub-portion disposed on a laser-exit side of the second type light-emitting chip and configured to guide the second type laser beam to the direction away from the base plate.
